(19) United States
(12) Patent Application Publication
(10) Pub. No.: US 2017/0181291 A1
(43) Pub. Date: Jun. 22, 2017

(54) Multi-component nanoinks for direct write applications

(71) Applicant: Sandia Corporation, Albuquerque, NM (US)

(72) Inventors: Nelson S. Bell, Albuquerque, NM (US); Timothy J. Boyle, Albuquerque, NM (US); Adam Cook, Albuquerque, NM (US); Fadi F. Abdeljawad, Albuquerque, NM (US)

(21) Appl. No.: 15/379,792

(22) Filed: Dec. 15, 2016

Related U.S. Application Data
(60) Provisional application No. 62/269,681, filed on Dec. 18, 2015.

(51) Int. Cl. H05K 3/12; B41J 2/01; C09D 11/03; C09D 11/52; C09D 11/36

(52) U.S. Cl. CPC H05K 3/125; C09D 11/52; C09D 11/36; C09D 11/03; B41J 2/01; H05K 3/1291

(57) ABSTRACT

The present invention is directed to printing mixed ink systems, such as silver-copper or silver-copper-ceramic nanoparticle inks.

### CROSS-REFERENCE TO RELATED APPLICATION

This application claims the benefit of U.S. Provisional Application No. 62/269,681, filed Dec. 18, 2015, which is incorporated herein by reference.

### STATEMENT OF GOVERNMENT INTEREST

This invention was made with Government support under contract no. DE-AC04-94AL85000 awarded by the U.S. Department of Energy to Sandia Corporation. The Government has certain rights in the invention.

### FIELD OF THE INVENTION

The present invention relates to printed electronics and, in particular, to multi-component nanoinks for direct write applications.

### BACKGROUND OF THE INVENTION

Additive manufacturing processes are generally associated with 3D printing of polymers and metals for prototyping and limited production of complex hardware. However, a suite of maskless digital printing technologies commonly referred to as direct write (DW) enable the printing of electronics systems and provide many advantages over gravure and sheet based techniques. Historically, printed circuit metallization has been accomplished using pure metal inks of either silver, gold, or copper particles dispersed in a solvent.

### SUMMARY OF THE INVENTION

The present invention is directed to a nanoink comprising a mixture of at least two of copper, silver, and gold nanoparticles dispersed in an organic solvent. The ratio of copper to silver nanoparticles can be less than 0.2:1 by weight. The mixture can comprise less than 40 wt % nanoparticles. The size of the nanoparticles can be less than 100 nm and, preferably, between 5 nm and 30 nm. The mixture can further comprise ceramic nanoparticles, including oxides of Group 4 elements such as titania, zirconia, or hafnia nanoparticles. For example, the organic solvent can be xylene. The organic solvent can further comprise a co-solvent, such as terpineol or white spirits, to improve printability. The organic solvent can further comprise a surfactant, such as a hyperdispersant, to disperse the nanoparticles.

The invention is further directed to a method to print a nanoink, comprising directly writing a nanoink on a substrate, the nanoink comprising a mixture of at least two of copper, silver, and gold nanoparticles dispersed in a solvent. For example, directly writing can include aerosol jet printing, syringe printing, or inkjet printing. The method can further comprise sintering the printed nanoink to an electrically conductive state. For example, the sintering can include laser, photonic, pulsed, or flash lamp sintering, or bulk thermal sintering. The sintering temperature can be less than 500° C.

As an example of the invention, silver-copper and silver-copper-hafnium oxide nanoinks were examined. High purity single metal and ceramic nanoparticles were synthesized and subsequently used to formulate stable multi-component ink systems. Following an aerosol-jet deposition printing process, selective laser sintering was used to post process multi-component depositions to an electrically conductive state. Mixed silver-copper ink systems which were laser sintered exhibited both homogeneous and heterogeneous microstructures and were experimentally observed to be influenced by the copper-to-silver content of the printing fluids. To this end, phase field modeling was employed and constitutive equations established which were used to computationally verify experimental observations. Fundamental material properties such as wetting angle, particle surface energies, and thermal diffusivities dominate microstructure evolution. The simulations indicate that the addition of up to 0.2 parts of copper to 1.0 part of silver can improve DC resistance properties in printed ink systems. Modeling suggests this may be a function of porosity minimization supporting the evolution of a highly conductive percolative path.

### BRIEF DESCRIPTION OF THE DRAWINGS

The detailed description will refer to the following drawings, wherein like elements are referred to by like numbers.

FIG. 1 is a graph of the DC resistance of bulk thermally processed printed inks as a function of increasing copper content.

FIG. 2 is a graph of the DC resistance of printed and infrared laser processed inks. Results are shown for focused laser power densities of 1130 W/mm² and 1194 W/mm².

FIG. 3(a) is a scanning electron micrograph (SEM) image of a 0.214 Cu:1 Ag hot plate annealed printed ink, indicating no phase separation. FIG. 3(b) is an elemental silver map of the image. FIG. 3(c) is an elemental copper map of the image.

FIG. 4(a) is an SEM image of an as-printed 0.75 Cu:1 Ag ink system. FIG. 4(b) is an elemental silver map of the image. FIG. 4(c) is an elemental copper map of the image.

FIGS. 5(a)-(f) are SEM images of laser annealed 1.0 Cu:0.75 Ag ink containing ceramic nanoparticles.

FIGS. 6(a)-(c) are schematic illustrations of the initial realizations of mono-disperse binary mixtures of spherical particles (disks in two dimensions), where red (black) denote material A (B). Three systems are examined using a phase-field simulation, where the total number of particles Nₛₚₕₑᵣₑ=2000. The number of particles, N_{A}, and particle volume fraction, V_{A}, of material A [N_{A}, V_{A}] is:(a) [500, 25%]; (b) [1000, 50%]; and (c) [1500, 75%].

FIGS. 7(a)-(c) are schematic illustrations of the microstructural evolution of the systems in FIGS. 6(a)-(c) at a simulation time of 26.6×10³.

FIGS. 8(a)-(c) are schematic illustrations depicting the microstructural evolution of a 3D system with a 40%/60% particle volume fraction of material A and B, respectively, at a simulation time of (a) t=0 (initial); (b) t=500; and (c) t=2300. In these figures, red (grey) denote material A (B).

### DETAILED DESCRIPTION OF THE INVENTION

The present invention is directed to single-solution, multi-component nanoinks for direct write processes. The mixing of metal, metal oxides (conducting or semi-conducting), and dielectric or insulating components to yield tunable microstructures by DW processes enables previously unobserved architectures in printed electronic networks. For example, the behavior of multi-component inks and particle suspensions leading to structural development can be viewed as phase separation between immiscible fluids, leading to complex structures (i.e., micelles, vesicles, lamellae) during aerosol-jet (AJ) deposition. The segregation of these components into complex structures is driven by mutual diffusion of immiscible components under total free energy gradients. Such complex structures are thought to result from non-uniformity of solvent evaporation rates, local variation in composition, post processing techniques, and ink rheological properties. These driving forces enable the development of complex structures similar to the complexity of diatom frustules on surfaces.

The following describes NP synthesis, particle dispersion and ink formulation, DW printing, characterization, and modeling for the multi-component nanoinks of the present invention. Solution precipitation and solvothermal synthesis of metal alkyls results in phase pure and monodispersed NPs suitable for custom ink formulation. Following material synthesis, metallic inks can be formulated by combining surfactants, NPs, and organic solvents. As deposited, NP ink systems are generally not electrically conductive and require post processing to impart functionality. A variety of mechanisms can be employed to sinter discrete nanoparticles to form conductive pathways and most notably include bulk thermal (hot plate or oven) and laser sintering.

### Metal Nanoparticle Synthesis

The multi-component inks of the present invention comprise two or more of the coinage metals (i.e., Cu, Ag, Au). High quality Cu, Ag, and Au nanoparticles can be synthesized according to literature methods. See S. Bunge et al., Nano Letters 3, 901 (2003). In particular, both Ag⁰ and Au⁰ NPs were synthesized following literature solution precipitation (SPPT) processes. For SPPT methods, a sample is heated or added to solvent at high temperature to initiate a decomposition of the metalorganic or organometallic precursors. The growth processes follow a La Mer growth mechanism, wherein a supersaturated solution is obtained at high temperatures and the strain released by forming a nucleation shower. Growth of the subsequent nuclei follows an Oswald ripening mechanism.

For the Ag⁰ NPs, silver acetate was heated in a mixture of toluene and oleylamine (ON) at 120° C. to generate high quality NPs of <20 nm in size. Similarly, Au⁰ NPs were synthesized using auric acid (HAuCl₄) in hexane and ON at reflux temperatures. These particles were also found to be <20 nm in size. Powder X-ray diffraction (PXRD) analyses indicated that these syntheses produced phase pure metallic species.

Likewise, Cu⁰ NPs were also synthesized following previous literature methods. See S. Bunge et al., Nano Letters 3, 901 (2003). The copper mesityl (Cu(Mes)) precursor is not commercially available, and was synthesized according to Eq. (1). The halide metathesis of the copper salt (CuCl) with the Grignard reagent ((Mes)MgBr) produced the metal alkyl Cu(Mes) in high yield, as an off-yellow powder when fully worked up.

$$\begin{matrix}CuCl + ( Mes ) MgBr {{\to }^{THF}}_{Dioxane} Cu ( Mes ) + MgBrCl & ( 1 ) \\ Cu ( Mes ) {{\to }^{oa / HDA}}_{300 ° C .} {Cu}^{0} & ( 2 )\end{matrix}$$

Once isolated, the Cu(Mes) precursor was dissolved in octylamine (OA) and then injected into hexadecylamine (HDA) at 300° C., according to Eq. (2). This decomposes the Cu(Mes) and reduces the Cu(l) to Cu(0). It was found that the Cu(Mes) needed to be cleaned (washed with hexanes and extracted with toluene) to obtain the highest quality precursor. If not washed and extracted, a substantial amount of ‘organic’ contaminant can be present that complicates subsequent ink formulation. With ‘clean’ precursors, high quality Cu⁰ NPs were synthesized in two sizes; small (red, 10-15 nm; 5 min. growth time) and large (copper, 50-80 nm; >40 min. growth time). The color noted is representative of the size of the particles.

### Ceramic Nanoparticle Synthesis

The multi-component ink can further comprise ceramic NPs. Therefore, the ink can be a high dielectric constant (k) material ink. High k materials are those that are capable of ‘holding’ a significant amount of charge. Some of the best of these materials come from the Group 4 family of compounds, such as zirconia (ZrO₂), titania (TiO₂), and hafnia (HfO₂). For example, hafnia can be prepared from several commercially available precursors, including hafnium chloride, carboxylate, ethoxide, and a neo-pentoxide derivative. See T. J. Boyle et al., lnorg. Chem. 51, 12075 (2012). These hafnia NPs can be synthesized using a SPPT process that employs 1-methyl imidazole and water in a 4:1 v/v ratio. See Y. Lee et al., Nanotechnology 19 (2008). A reaction mixture of Melm:H₂O and an appropriate hafnia precursor can be heated and refluxed for 1 hour. The precipitate can be subsequently removed by centrifugation, washed with hexanes, and air dried. PXRD patterns of hafnia NPs synthesized with this process showed that the ‘as generated’ material was amorphous as synthesized and extracted. However, crystalline material can be isolated when heated at to 800° C. Transmission electron microscope (TEM) images revealed random shaped particles that were polydispersed.

### Ink Formulation and Characterization

Silver and copper inks showed concentration dependent behavior towards aggregation. Initially, the Ag ink begins as a diluted state in a fine dispersion, but begins to aggregate rapidly. The Cu ink was present as >100 nm clusters, but dilution in xylene lead to greater aggregation and sedimentation. Adding terpineol did not lead to stabilization of either system, but it may slow the aggregation process and create a broader distribution of aggregate size.

While all NP systems evaluated were sensitive to dilution, the silver system showed ultrasonic agitation can affect the floc size and create a bimodal particle size distribution. A potential reason for the observed instability is a destabilization of the surfactant structure of the nanoparticle systems, leading to particle fusion. When additional solvent is added, there may be an equilibrium of surfactant molecules that is achieved, creating a less stable nanoparticle system. All inks exhibit the same behavior in the initial formulation, indicating more or less stability.

To improve the long-term stability and aging qualities of the copper ink to be used in the mixed phase metallic particle dispersions, hyperdispersants can be added to prevent particle agglomeration and precipitation from solution. Solsperse™ dispersing agents, commercially available from Lubrizol Corporation, are compatible with the copper ink chemistry. However, to maintain compatibility with the printing and laser processing techniques used during deposition, the dispersing agent must be removed at temperature below 500° C. Thermal gravimetric analysis (TGA) showed that Solsperse 9000 was well suited for ink formulation, as 85% of the dispersant's organic content can be removed below 400° C. with full elimination occurring just above 500° C. Therefore, a 20 weight percent copper nanoparticle ink was formulated using a mixture of xylene, white spirits, and Solsperse 9000. The addition of Solsperse 9000 resulted in well dispersed copper ink solutions that resisted agglomeration and maintained a uniform distribution required for subsequent printing. Dynamic light scattering (DLS) also showed a strong ability of the dispersing agent to resist bimodal particle distribution evolution in copper inks which is thought to be beneficial during the AJ printing and processing phases.

### Preparation of Ag-Cu NP Mixed Inks

Eleven mixed ink systems were prepared that varied in composition from 100 percent pure silver ink to 100 percent pure copper ink. Commercially sourced silver NPs, available from UT-Dots, Inc., were used in formulating mixed inks of silver and copper for evaluation of phase separation properties. The commercial silver ink was shown to have a mean particle size particle of 9-30 nm, which was very close to that of the SPPT-synthesized copper NPs. However, the solids concentration of the silver ink was measured to be 40 weight percent, twice that of the copper ink. In all instances, the total volume of each mixed ink was maintained at 1 mL, a convenient amount for AJ printing. For example, a mixed ink having 14.2 wt % copper and 85.8 wt % silver was formulated by taking 0.3 mL of the 20 wt % copper ink and 0.7 mL of the commercial 40 wt % silver ink. Formulation details and mixture ratios of the various copper-to-silver inks used are shown in Table 1.

TABLE 1
Mixed ink systems evaluated

| Parts Cu | Parts Ag | | |
|---|---|---|---|
| Ink | Ink | Ink Mix Ratio | Solution |
| 20 wt % | 40 wt % | Cu:Ag | ID |
| 20 | 0 | Cu | 10 |
| 18 | 4 | 4.500 | 9 |
| 16 | 8 | 2.000 | 8 |
| 14 | 12 | 1.167 | 7 |
| 12 | 16 | 0.750 | 6 |
| 10 | 20 | 0.500 | 5 |
| 8 | 24 | 0.333 | 4 |
| 6 | 28 | 0.214 | 3 |
| 4 | 32 | 0.125 | 2 |
| 2 | 36 | 0.056 | 1 |
| 0 | 40 | Ag | 0 |

### Aerosol Jet Printing and Laser Sintering

An AJ deposition method was used to precisely print each of the 11 inks shown in Table 1. The process allows for the non-contact deposition of a nanoparticle ink by first atomizing a small quantity of the liquid ink and subsequently focusing the aerosolized product through a series of aerodynamic lenses resulting in deposition through a 50 to 300 micron orifices. A simple modified Van Der Pauw test pattern was printed onto glass slides and used to evaluate DC electrical properties of the printed inks. The pattern allowed for the calculation of resistance by applying a fixed current to the circuit and allowing the compliance voltage to float as needed. The arrangement minimized the effects of contact resistance and resulted in a more accurate measurement than simple two point techniques.

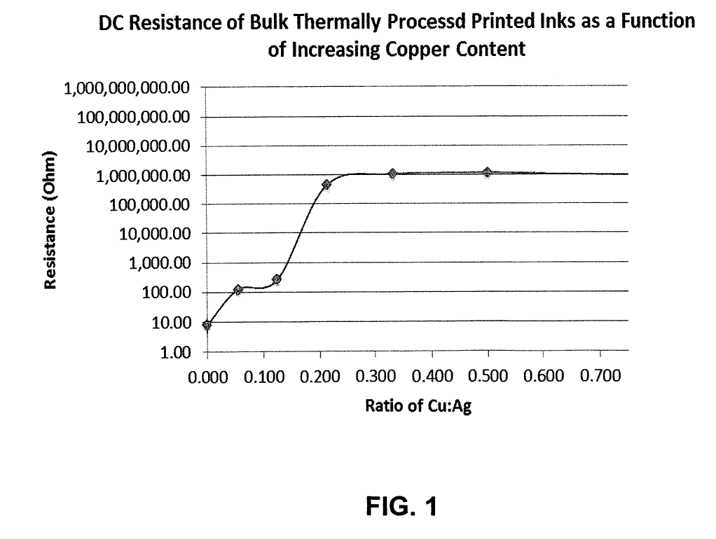

Copper NPs readily oxidize when heated under atmospheric conditions and electrical properties consequently suffer. FIG. 1 shows DC resistance properties of printed and hot plate annealed inks containing increasing amounts of copper. Samples printed in pure silver and thermally annealed resulted in the lowest measured resistance. For copper content greater than 16.7 wt %, oxidation of the copper in solution dominated and resulted in megaohmic conductors.

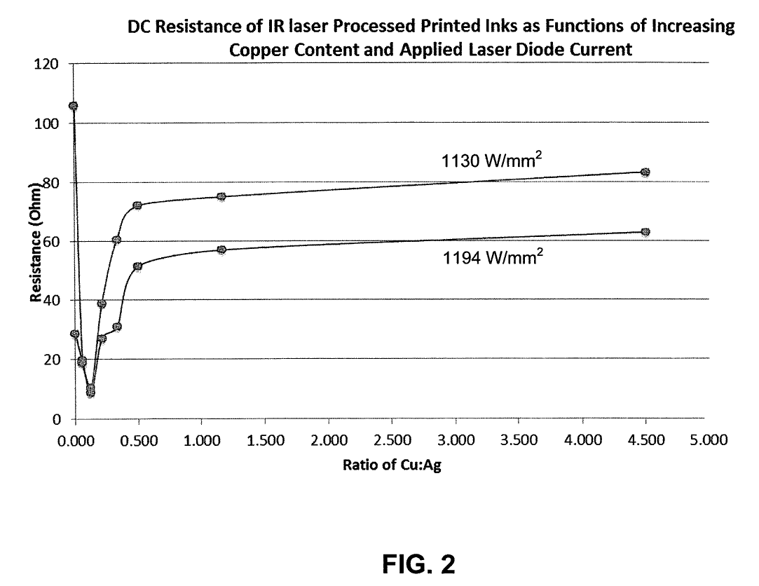

Laser sintering is an attractive alternative to bulk thermal processing since oxidation kinetics have been shown to be minimized in comparison to conventional heating processes. See I. Heodorakos et al., Applied Surface Science 336, 157 (2015); and T. Park and D. Kim, Thin Solid Films 578, 76 (2015). A continuous wave 835 nm infrared (IR) laser having an effective spot size of 20 microns was used to selectively sinter printed test structures. Power densities ranging up to 2387 W/mm² were evaluated as increasing laser power has been shown in the literature to result in improved bulk DC resistivity. Substantially lower resistance values for equivalent circuits were obtained by laser processing as compared to bulk thermal processing. As shown in FIG. 2, 0.67 amp of applied current to the IR laser diode, corresponding to a power density of 1130 W/mm², was experimentally determined to be the minimum power level required to effect laser sintering of the ink systems evaluated. Laser processing at 1194 W/mm² at an applied current of 0.75 amp resulted in still low DC resistance values of sintered circuits. Processing above 1194 W/mm² was generally found to result in ablation.

Visual inspection and optical microscope analysis of printed and laser sintered test structures revealed that varying the ratio of copper-to-silver present dramatically changed not only the electrical properties of a conductor but appeared to promote a phase separation of metallic elements in the laser sintered depositions. The effect was not observed with any samples heated on a hot plate and is thought to be the result of a laser-sintering-dependent phenomenon governed in part by reaction kinetics, differential surface energies of silver and copper nanoparticles, and the ability of discrete metal components in the ink to preferentially absorbed energy delivered from the IR laser source.

### Microscopy of Printed and Laser Processed Materials

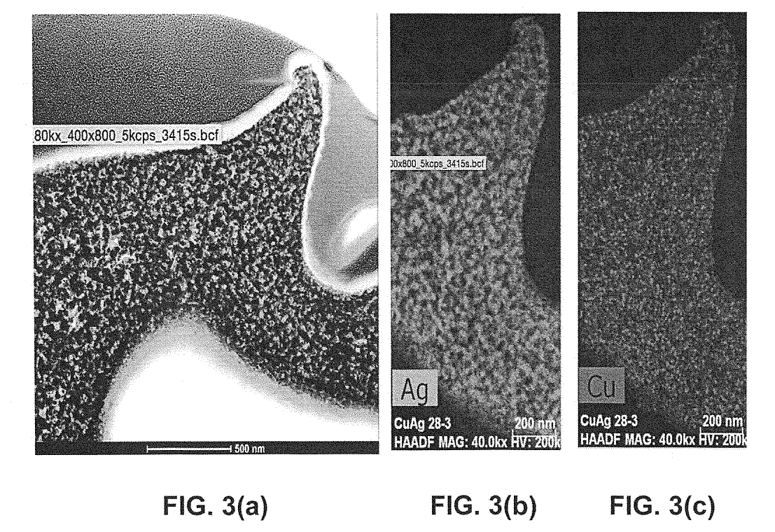

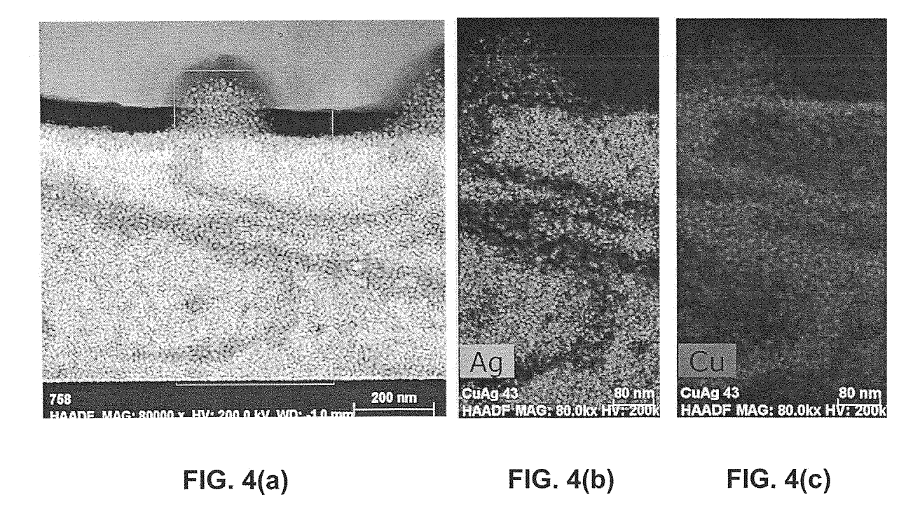

Microscopy revealed the formation of homogeneous and heterogeneous annealed phases of mixed silver-copper ink systems. For example, as shown in FIGS. 3(a)-(c), no evidence of species migration or separation of silver and copper elements was observed with Solution 3 (0.214 Cu:1 Ag). This sample was heated on a hot plate and exhibited good resistance properties. By contrast, species segregation was observed in both the as-printed and annealed depositions when printed with Solution 6 (0.75 Cu:1 Ag). These depositions showed swirls of copper NP bands within a predominantly silver film, as shown in FIGS. 4(a)-(c).

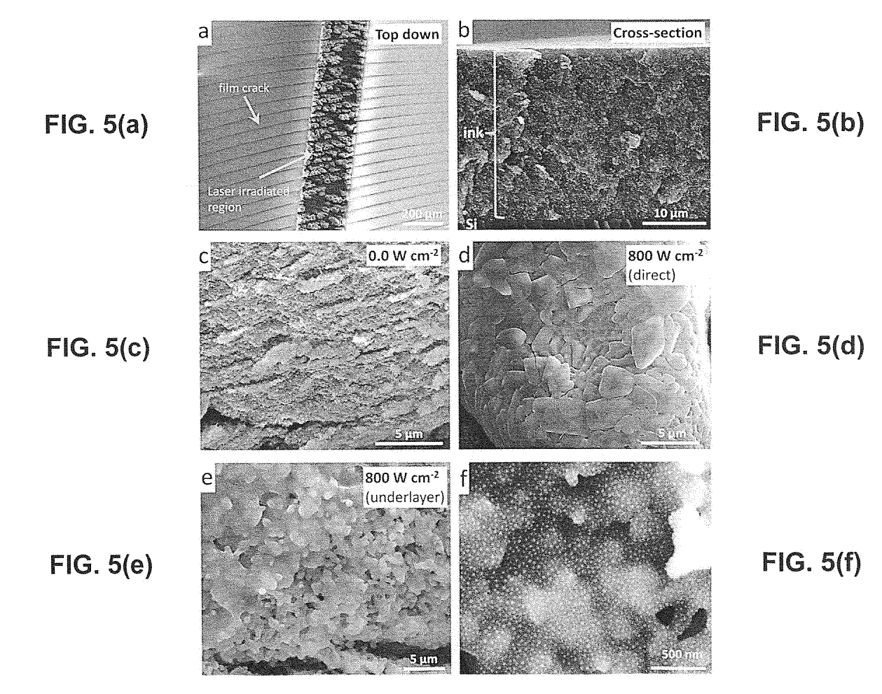

TiO₂ particles were introduced into the ink system described above. A well dispersed ink was formulated and laser sintering was effective in annealing the film. As shown in FIG. 5, ceramic NPs were uniformly dispersed into the bulk of the deposit produced with a laser sintered three-component ink system (1.0 Cu:0.75 Ag:0.75 Ceramic TiO₂). FIG. 5(a) shows a top-down view of a ˜40 μm thick film cast onto a silicon substrate. The ink was exposed to 808 nm continuous wave (CW) laser scanning a ˜0.2 mm² square region at an irradiance of 800 W cm⁻². FIG. 5(b) shows a cross-section of unexposed ink layer on Si. FIG. 5(c) shows a peel-away of the unexposed ink which reveals a lamellar/particulate morphology. FIG. 5(d) shows a top-down view of a region in direct exposure to the laser and displays complete annealing indicated by the relatively uniform (platelet) morphology. The cross-section of FIG. 5(e) shows an annealed layer underlying the direct exposure. A comparison of FIGS. 5(c) and 5(e) indicates thermal annealing throughout the thickness of the ink layer.

### Modeling

Under continuous operation, microstructures of binary metallic particles evolve over time in response to a multitude of cues, e.g., temperature and stress. In order to understand and predict the stability of these morphologies and their temporal evolution over extended time scales, a mesoscale approach is required, which incorporates both atomic scale information and evolving microstructures. To this end, a diffuse-interface, phase field model was used to evaluate the microstructural evolution of three-phase systems (two metals, which are denoted A and B, and a pore phase) that accounts for bulk thermodynamics and interfacial energies of the evolving phases. The starting point of the phase field treatment is the introduction of structural order parameters that describe each phase in the system. Here, (φ_{A}, φ_{B}, φ_{C}) was used to describe a three-phase system that is comprised of a binary mixture of two metals, {A, B}, with (φ_{A}, φ_{B}), respectively, in addition to the solvent/pore phase (φ_{C}). For the Ag-Cu system, material A (B) denotes Ag (Cu). Moreover, by enforcing φ_{A}+φ_{B}+φ_{C}=1, where the phase fields now are measures of the volume fraction of phases, one can write φ_{C} in terms of the other two phase fields. Next, a coarse-grained free energy functional of this three-phase system, Fₜₒₜ is written as:

$${F}_{tot} = \int dr [ {f}_{0} ( {φ}_{A} , {φ}_{B} , {φ}_{C} = 1 - {φ}_{A} - {φ}_{B} ) + \frac{{ɛ}_{A}^{2}}{2} {\vert ∇ {φ}_{A} \vert}^{2} + \frac{{ɛ}_{B}^{2}}{2} {\vert ∇ {φ}_{B} \vert}^{2} ] ,$$

where f₀ is the homogeneous bulk free energy density. ε_{A} and ε_{B} are the gradient energy terms, which set the interface energy of A-pore and B-pore surfaces. The following form for the free energy density of the grain microstructure was adopted:

f₀=H_{A}φ_{A}²(1−φ_{A})²+H_{B}φ_{B}²(1−φ_{B})²+W[φ_{A}²φ_{B}²+2(1−φ_{B}−φ_{A})²(φ_{A}²+φ_{B}²+φ_{A}φ_{B})],

where H_{A}, H_{B}, and W are parameters that set the energy scale of the system. The interface energy and width of each phase are uniquely defined via the model parameters ε_{A}, ε_{B}, H_{A}, H_{B} and W.

The phase fields used represent conserved quantities; therefore, with the aid of variational principles, the governing equations for the spatio-temporal evolution of φ_{A} and φ_{B} follow from

$$\frac{\partial {φ}_{i}}{\partial t} = ∇ \cdot {M}_{i} ∇ ( \frac{\partial {F}_{tot}}{\partial {φ}_{i}} ) , i = A , B ,$$

where the model parameters M_{A} and M_{B} are the atomic mobility of material A and B, respectively. See Cahn and Hilliard, J. Chem. Phys. 28, 258 (1958). The following assumptions are made in the modeling treatment:
1) Three phase fields are introduced to describe each phase. A natural extension of this model would be to introduce structural order parameters to describe grains with various crystallographic orientations for each phase.
2) Microstructural evolution is mainly driven by the contribution to the total energy due to interfaces. Temperature effects due to the strength of the laser beam and the overall heating effect are incorporated through the model parameters describing atomic diffusivity and interface energy.
3) Surface self-diffusion is assumed to be the dominant mass transport mechanism. This is done in the model by letting M_{A}=4M₀φ_{A}(1−φ_{A}) and M_{B}=4M₀φ_{B}(1−φ_{B}), where M₀ is the intrinsic mobility. These forms for the mobility functions ensure that the mobility is M₀ at the center of the interface and vanishes elsewhere, i.e., in the bulk.

To examine binary mixtures of materials A and B, the packing algorithm by Skoge et al., Phys. Rev. E 74, 041127 (2006) was used to generate realizations of Nₛₚₕₑᵣₑ hard spheres (disks in two dimensions) with various radii and total packing density. Motivated by the experimental setup, the particle radii of materials A and B were set to be the same and only the particle volume fraction of A, V_{A}=N_{A}/Nₛₚₕₑᵣₑ, and B, V_{B}=N_{B}/Nₛₚₕₑᵣₑ, where N_{A} and N_{B} are the total number of particles of A and B, respectively, were varied. In this simulation, Nₛₚₕₑᵣₑ=2000 and the number of particles of A was set to N_{A}=500, 1000 and 1500, which yielded a particle volume fraction of V_{A}=25%, 50% and 75%, respectively.

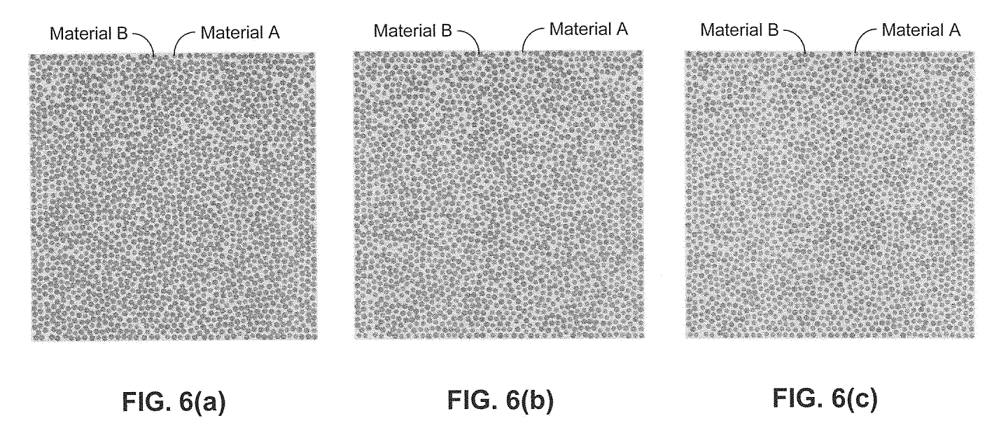

FIGS. 6(a), (b) and (c) show the initial realization of systems with a particle volume fraction of material A of (a) 25% [N_{A}=500 ], (b) 50% [N_{B}=1000] and (c) 75% [N_{A}=1500]. In these panels, red (black) particles denote material A (B), where again A (B) represent Ag (Cu).

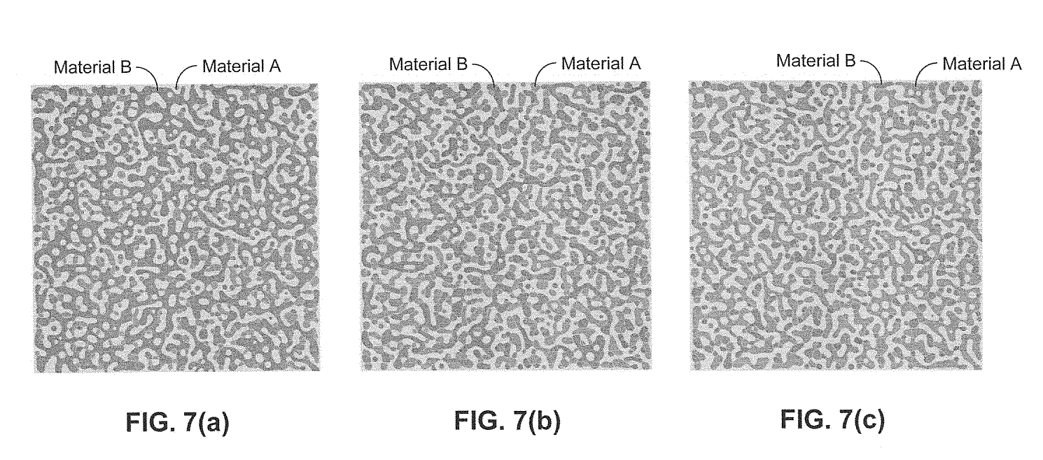

At a simulation time of 26.6×10³, FIGS. 7(a), (b) and (c) depict the microstructures corresponding to the initial configurations in FIG. 6(a), (b) and (c), respectively. Agglomeration of the particles of both phases is seen, which leads to the reduction of the system energy via the decrease in the total interfacial area for systems, where the number of particles, N_{A}, and particle volume fraction, V_{A}, of material A [N_{A}, V_{A}] is:(a) [500, 25%], (b) [1000, 50%], and (c) [1500, 75%].

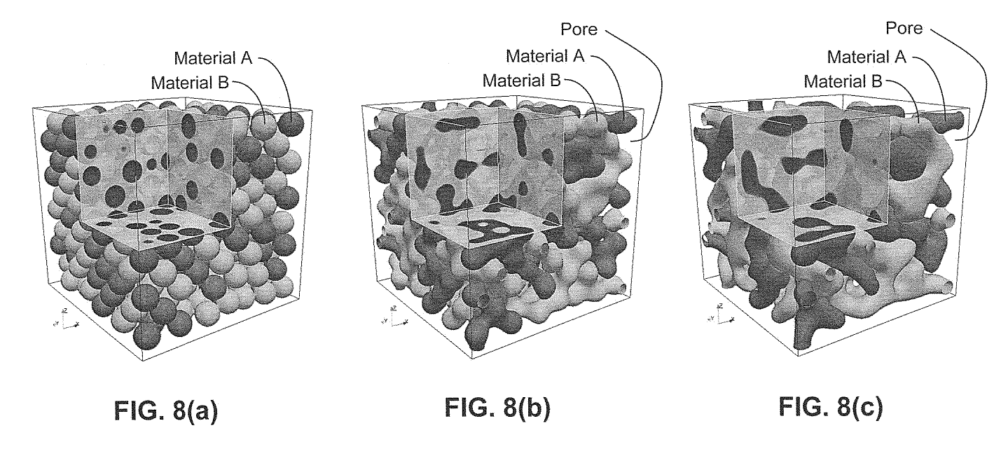

Next, the microstructural evolution of a binary mixture with a particle volume fraction of material A and B of 40% and 60%, respectively, was examined in three dimensions. For this simulation, a total of Nₛₚₕₑᵣₑ=500 was used. The snapshots shown in FIGS. 8(a), (b), and (cf) reveal that pores open up, where the average pore space increases with the microstructure evolution. This is primarily due to the fact that the evolution leads to reduction in the total interfacial area of both phases (material A and B), which in turn yields larger pores. These simulations are in agreement with the experimental observation in FIG. 4(a).

The present invention has been described as multi-component nanoinks for direct write applications. It will be understood that the above description is merely illustrative of the applications of the principles of the present invention, the scope of which is to be determined by the claims viewed in light of the specification. Other variants and modifications of the invention will be apparent to those of skill in the art.

We claim:

1. A nanoink, comprising a mixture of at least two different metallic nanoparticles selected from group consisting of copper, silver, and gold nanoparticles dispersed in an organic solvent.

2. The nanoink of claim 1, wherein the mixture comprises silver and copper nanoparticles.

3. The method of claim 2, wherein the ratio of copper to silver nanoparticles is less than 0.2:1 by weight.

4. The nanoink of claim 1, wherein the mixture comprises less than 40 wt % nanoparticles.

5. The nanoink of claim 1, wherein the size of the nanoparticles is less than 100 nm.

6. The nanoink of claim 5, wherein the size of the nanoparticles is between 5 nm and 30 nm.

7. The nanoink of claim 1, wherein the mixture further comprises ceramic nanoparticles.

8. The nanoink of claim 7, wherein the ceramic nanoparticles comprise oxides of Group 4 elements.

9. The nanoink of claim 8, wherein the ceramic nanoparticles comprise titania, zirconia, or hafnia nanoparticles.

10. The nanoink of claim 1, wherein the organic solvent comprises xylene.

11. The nanoink of claim 1, wherein the organic solvent comprises a co-solvent to improve printability.

12. The nanoink of claim 1, wherein the organic solvent further comprises a surfactant to disperse the nanoparticles.

13. The nanoink of claim 12, wherein the surfactant comprises a hyperdispersant.

14. A method to print a nanoink, comprising directly writing a nanoink on a substrate, the nanoink comprising a mixture of at least two different metallic nanoparticles selected from the group consisting of copper, silver, and gold nanoparticles dispersed in an organic solvent.

15. The method of claim 14, wherein the mixture comprises copper and silver nanoparticles.

16. The method of claim 14, wherein the directly writing comprises aerosol jet printing, syringe printing, or inkjet printing.

17. The method of claim 14, further comprising sintering the printed nanoink to an electrically conductive state.

18. The method of claim 17, wherein the sintering comprises laser, photonic, pulsed, or flash lamp sintering.

19. The method of claim 18, wherein the power density of the sintering is less than 1194 W/mm².

20. The method of claim 17, wherein the sintering comprises bulk thermal sintering.

21. The method of claim 17, wherein the sintering temperature is less than 500° C.
